(19) United States
(12) Patent Application Publication
(10) Pub. No.: US 2012/0101760 A1
(43) Pub. Date: Apr. 26, 2012

(54) Method of Enabling Calibration of a Current Transformer, and Associated Apparatus

(76) Inventors: Praveen Sutrave, Sewickley, PA (US); Christopher David Wells, McMurray, PA (US)

(21) Appl. No.: 12/912,108

(22) Filed: Oct. 26, 2010

(51) Int. Cl. G01R 35/00; G01R 19/00

(52) U.S. Cl. 702/85; 324/76.11

(57) ABSTRACT

An improved current transformer apparatus includes a current transformer upon which are stored a number of calibration values which can be used when connecting the current transformer to a metering device. An improved method of enabling calibration of the current transformer involves deriving from a signal detected from the current transformer a number of calibration values for the current transformer and storing the calibration values in a storage disposed on the current transformer. A metering device retrieves from the storage the calibration values and applies the calibration values to a signal from the current transformer to generate a calibrated output.

### BACKGROUND

1. Field

The disclosed and claimed concept relates generally to current transformers and, more particularly, to a current transformer having a number of calibration values provided therewith, and an associated method.

2. Related Art

Current transformers of various types are generally known. Typically, a current transformer may include an annular iron core about which a plurality of windings are wrapped. In use, an electrical conductor is situated in the hole of the annular iron core, and when an alternating current is passed through the conductor, the conductor serves as a primary conductor to induce a current in the windings, which serve as a secondary conductor. Depending upon the application, the wire used for the windings is connected with a meter which detects a current from the windings and which responsively provides an output which may be, for instance, a measurement of the current. However, while current transformers have been generally effective for their intended purposes, they have not been without limitation.

As can be understood from the manufacturing arts, current transformers that are manufactured using the same equipment even on the same day are not exactly identical to one another. As such, current transformers that are installed in a factory setting into another system are calibrated during the installation process. That is, an extremely precise calibration load and an extremely precise calibration meter are applied to the current transformer and the output from the current transformer is obtained. By way of example, the calibration might determine that the current which is output by the current transformer might be very slightly greater or less than what is expected given the current flowing through the primary conductor, or the current in the current transformer might be slightly out of phase with that of the primary conductor, or both. Additionally or alternatively, it is possible that at lower currents in the primary conductor, the current in the current transformer is far less than what it should be.

When the current transformer is installed into a system in a factory setting, therefore, the aforementioned signal errors detected from the current transformer are used to calibrate whatever metering apparatus is connected with the current transformer. That is, a channel of the metering apparatus might have adjustable dials which are adjusted such that the output from the current transformer is corrected based upon the aforementioned errors such that the output from the metering apparatus correctly reflects the current flowing through the primary conductor. Other metering apparatuses might be calibrated in different fashions.

It is noted, however, that the ability to obtain accurate output from the current transformer in order to determine the aforementioned errors relies largely upon the availability of extremely accurate metering devices and extremely accurate calibration loads that can be applied to the current transformer. Equipment with such accuracy levels typically is found only in a factory setting. As such, while the calibration of current transformers can be accurately performed when current transformers are installed in a factory setting, difficulty has been experienced in attempting to calibrate a current transformer when it is installed into another system in the field.

Other difficulties have been encountered during field installation when a current transformer is to be installed on one of a plurality of conductors. That is, in an environment in which a plurality of conductors exist, while a current transformer can be installed to be situated about one of a plurality of conductors, the process of discerning the identity of any particular conductor as being, say, the conductor that serves a particular load or location, has been difficult.

It thus would be desirable to provide an improved current transformer or method or both that overcome these and other shortcomings associated with the relevant art.

### SUMMARY

An improved current transformer apparatus includes a current transformer upon which are stored a number of calibration values which can be used when connecting the current transformer to a metering device. An improved method of enabling calibration of the current transformer involves applying a high precision known load to the current transformer, deriving from a signal detected from the current transformer a number of calibration values for the current transformer, and storing some of the calibration values in a storage disposed on the current transformer. When the current transformer is installed, such as in a field installation, the metering device to which the current transformer is connected retrieves from the storage the calibration values and applies at least some of the calibration values to a signal detected from the current transformer to generate a calibrated output from the metering device. An improved method of determining that a current transformer is situated about a conductor includes applying a predefined load to a particular conductor from among a plurality of conductors and making a determination from a signal detected from a particular current transformer responsive to the predefined load that the particular current transformer is situated about the particular conductor.

Accordingly, an aspect of the disclosed and claimed concept is to provide an improved current transformer apparatus that includes a current transformer and a storage disposed on the current transformer wherein the storage has stored therein a number of calibration values for the current transformer.

Another aspect of the disclosed and claimed concept is to provide an improved method of enabling calibration of a current transformer.

These and other aspects of the disclosed and claimed concept are provided by an improved method of enabling calibration of a current sensor, the general nature of which can be stated as including applying a known load to a conductor that is disposed in proximity to the current sensor, detecting from the current sensor a signal responsive to the known load, deriving from the signal and the known load a number of calibration values for the current sensor, and storing on the current sensor at least a portion of the number of calibration values.

Other aspects of the disclosed and claimed concept are provided by an improved current sensor apparatus, the general nature of which can be stated as including a current sensor structured to be connected with a metering device, a non-volatile storage disposed on the current sensor and having stored therein a number of calibration values for the current sensor, and a communications system connected with the storage and structured to communicate at least a portion of the number of calibration values to the metering device.

Still other aspects of the disclosed and claimed concept are provided by an improved method of calibrating a current sensor, the general nature of which can be stated as including connecting the current sensor with a metering device, retrieving a number of calibration values for the current sensor, and applying at least a portion of the number of calibration values to a signal received from the current sensor to generate a calibrated output from the metering device.

### BRIEF DESCRIPTION OF THE DRAWINGS

A further understanding of the disclosed and claimed concept can be gained from the following Description when read in conjunction with the accompanying drawings wherein:

FIG. 1 is a schematic depiction of an improved current transformer apparatus of the disclosed and claimed concept during the process of deriving a number of calibration values for the current transformer;

FIG. 2 is a schematic depiction of the current transformer apparatus of FIG. 1 connected with a metering device, such as during a field installation; and

FIG. 3 is a schematic depiction of a plurality of current transformers, such as with the current transformer apparatus of FIG. 1, being installed in a system, such as in a field installation.

Similar numerals refer to similar parts throughout the specification.

### DESCRIPTION

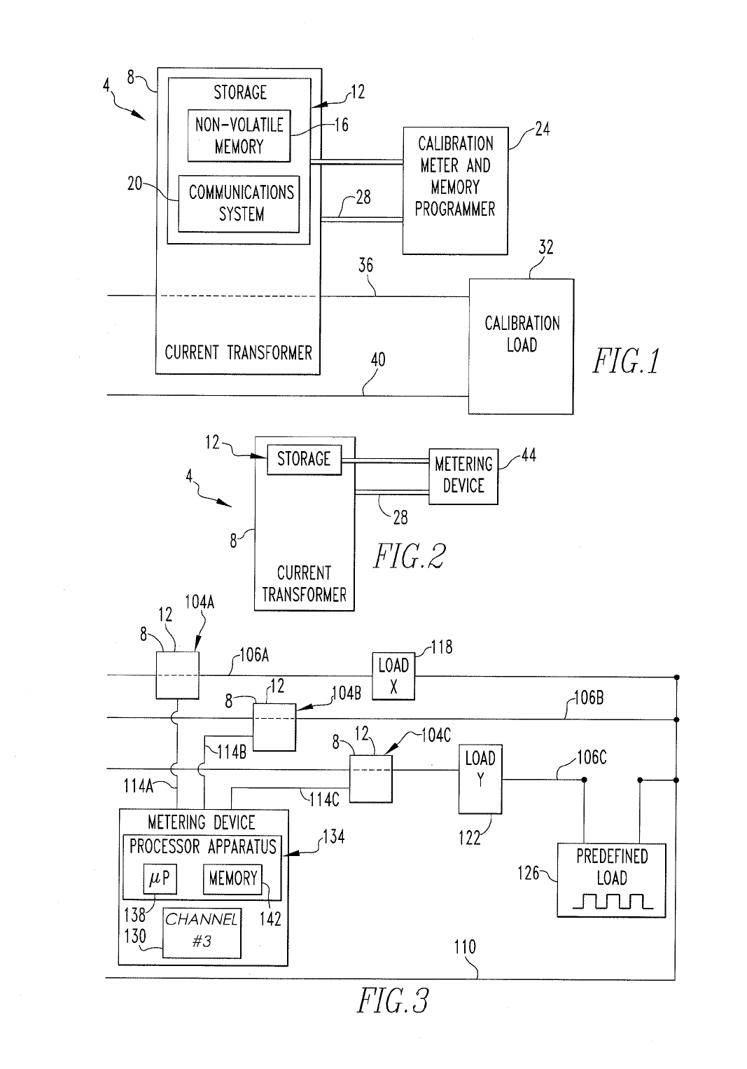

An improved current sensor apparatus which, in the depicted exemplary embodiment, is a current transformer apparatus 4 in accordance with the disclosed and claimed concept is depicted in FIGS. 1-3. The current transformer apparatus 4 includes a current sensor which, in the depicted exemplary embodiment, is a current transformer 8 that can be any of a wide variety of current transformers such as are generally known in the relevant art. As employed herein, the expression “current sensor” and variations thereof shall refer broadly to any of a wide variety of devices that are structured to detect current, and expressly includes a current transformer. The current transformer apparatus 4 further comprises a storage 12 that is disposed on the current transformer 8 and which has stored therein data that may include a number of calibration values for the current transformer 8, an identification of the current transformer 8 such as a current capacity, model and serial numbers, and the like without limitation. While the current transformer apparatus 4 can be installed into another system in a factory setting, the current transformer apparatus 4 can also be advantageously installed into another system in a field environment. This is because the calibration values and other data stored in the storage 12 can be retrieved by a metering device in the field and employed in converting a signal that is received from the current transformer 8, such as a current indicative of a current flowing through a conductor extending through the current transformer 8, into a calibrated output from the metering device.

As will be set forth in greater detail below, during field installation of the current transformer apparatus 4, one or more instances of the current transformer apparatus 4 can be installed about one or more conductors. A predefined load that has been applied to a particular conductor can result in a signal that is detected from a particular current transformer apparatus 4, which enables a determination that the particular current transformer apparatus 4 is situated about the particular conductor. It is noted, however, that the determination that a particular current transformer apparatus 4 is situated about a particular conductor can be performed without the use of the storage 12, meaning that such an improved method can employ any type of current transformer 8 to determine that the current transformer 8 is situated about a particular conductor.

As can be understood from FIG. 1, the storage 12 comprises a non-volatile memory 16 and a communications system 20. The non-volatile memory 16 can include any one or more of a variety of storage devices that function to store data, such as RAM, ROM, EPROM, EEPROM, FLASH, and the like without limitation. The communications system 20 can be likewise in any of a variety of configurations, such as being in the form of a wire connector that can be connected with a metering device, and the like. In the example depicted generally in FIG. 1, the communications system 20 is depicted as including a set of wires that extend between the storage 12 and a device referred to herein as a calibration meter and memory programmer 24, although other configurations are possible. In this regard, it is noted that the storage 12 could be in the form of an RFID chip that would include both the non-volatile memory 16 and would provide as the communications system 20 a wireless communication capability that could wirelessly communication the contents of the storage 12 to a metering device. It is also noted that the storage 12 can be disposed internally within the current transformer 8 or could be attached externally thereto, such as when an off-the-shelf current transformer might be retrofitted with a storage to form the current transformer 8 by physically connecting the two together.

During the process of enabling calibration of the current transformer 8, a pair of leads 28 of the current transformer 8 are connected with the calibration meter and a memory programmer 24, and the communications system 20 is likewise connected with the calibration meter and memory programmer 24. A calibration load 32 which provides a known load to the current transformer 8 is applied to the current transformer 8. More particularly, the calibration load 32 draws a current in a primary calibration conductor 36 which extends through a hole formed in an annular iron core (not expressly depicted herein) of the current transformer 8 and through a neutral calibration conductor 40 that are connected with the calibration load 32.

While FIG. 1 depicts the calibration meter and memory programmer 24 as being separate from the calibration load 32, it is understood that the two components may be connected together and, indeed, the calibration load 32 likely is controlled by the calibration meter and memory programmer 24. After one or more known loads are applied with the calibration load 32 to the current transformer 8, the calibration meter and memory programmer 24 detects the various signals via the leads 28 from the current transformer 8 and derives from the various signals a number of calibration values for the current transformer 8. The calibration values might include, by way of example, a gain value, a phase correction value, or both. The number of calibration values might additionally or alternatively include a non-linearity factor that is usable in a particular current range that is being detected by the current transformer 8. In this regard, it is noted that the data which can be stored in the non-volatile memory include identification data that may comprise data elements that are indicative of an ampere capacity of the current transformer 8, a model number and/or serial number of the current transformer, and the like.

Once the signals have been detected from the current transformer 8 and have been used by the calibration meter and memory programmer 24 to derive the number of calibration values for the current transformer 8, the calibration meter and memory programmer 24 programs the number of calibration values into the non-volatile memory 16 in any of a variety of well-understood fashions. The calibration meter and memory programmer 24 can additionally program into the non-volatile memory 16 the aforementioned identification data for the current transformer 8, or such identification data may have already been stored in the non-volatile memory 16 prior to connection with the calibration meter and memory programmer 24.

The primary calibration conductor 36 is then removed from the current transformer 8, and the current transformer apparatus 4 with its current transformer 8 and its programmed storage 12 can then be shipped for field installation. Advantageously, therefore, the current transformer 8 is shipped with a storage 12 that includes in its non-volatile memory data that includes one or more calibration values for the current transformer and/or one or more pieces of identification data that include data elements indicative of certain aspects of the current transformer 8. Since the calibration values are derived in a factory setting from a highly accurate calibration meter and memory programmer 24 and from a highly accurate calibration load 32, the calibration values are highly accurate and can be advantageously used in the field by a metering device to which the current transformer 8 is connected to generate a calibrated output from the current transformer 8. Moreover, if a plurality of instances of the current transformer apparatus 4 are being installed in a system in the field, the calibration values for any particular current transformer apparatus 4 are physically stored directly on the current transformer apparatus 4, with the result that it is unnecessary for a technician to record, input, or otherwise work with the particular calibration values themselves. That is, when each of the instances of the current transformer apparatus 4 are connected with a metering device, the metering device retrieves from the individual instances of the current transformer apparatus 4 the associated calibration values and applies the associated calibration values to the signal that is received from the current transformer 8 in order to generate a calibrated signal and to thereby provide from the metering device a calibrated output that corresponds with the current transformer 8.

FIG. 2 depicts the current transformer apparatus 4 connected with a metering device 44, such as in a field installation. More particularly, the current transformer 8 of the current transformer apparatus 4 can be said to be calibrated by connecting the current transformer 8 with the metering device 44, retrieving the calibration values for the current transformer 8 from the storage 12, and applying the calibration values to the signals received from the current transformer 8 to generate a calibrated signal from the current transformer 8 and thus also a calibrated output from the metering device 44.

A field installation of the current transformer apparatus 4 is depicted generally in FIG. 3. As can be seen, the exemplary installation includes three current transformer apparatuses 104A, 10413, 104C, are similar to the current transformer apparatus 4, and each has a current transformer 8 and a storage 12. The current transformer apparatuses 104A, 104B, 104C each have a conductor 106A, 106B, 106C, respectively, passing therethrough which could be on the same phase or on different phases without departing from the present concept. Also depicted is a neutral 110 to which the conductors 106A, 106B, 106C are connected.

The metering device 44 includes three channels 114A, 114B, 114C which serve as inputs on the metering device 44, with the current transformer apparatuses 104A, 104B, 104C being connected with the channels 114A, 114B, 114C, respectively. As has been set forth above, the calibration values that are stored in the storage 12 of each of the current transformer apparatuses 104A, 104B, 104C are retrieved by the metering device 44, and the retrieved set of calibration values are applied to the signal detected from the current transformer 8 of the corresponding current transformer apparatus 104A, 104B, 104C in order to generate a calibrated signal from each such current transformer 8. As such, a plurality of current transformers 8 can be calibrated by providing on the current transformer 8 the storage 12 which has stored therein the calibration values and by retrieving the calibration values from the storage 12 and applying them to the signal received from the corresponding current transformer 8.

Another improved method in accordance with the disclosed and claimed concept enables a determination that a particular current transformer 8 is situated about a particular conductor 106A, 106B, 106C. That is, the plurality of conductors 106A, 106B, 106C may be indistinguishable from one another in the vicinity of the metering device 44, and thus a predefined load 126 is advantageously applied to a particular one of the conductors 106A, 106B, 106C, and whatever signals are detected from the current transformers 8 are analyzed to identify the current transformer 8 having an output that indicates the existence of the predefined load 126 on the associated conductor 106A, 106B, 106C. The predefined load 126 is depicted schematically in FIG. 3 and may include one or more inductive loads and/or capacitive loads and/or resistive loads that operate in a predetermined fashion that causes the predefined load 126 to draw from a conductor a current that varies in a predetermined fashion with time. By way of example, the predefined load might cause a particular current draw for ten seconds, followed by no current draw for ten seconds, followed by the particular current draw again for ten seconds, and so forth. Since the predefined load 126 is unique in comparison with electrical loads typically encountered, its presence can be detected by the metering device 44 regardless of the presence of other loads on the same conductor.

For example, FIG. 3 depicts a load X 118 on the conductor 106A and a load Y 122 on the conductor 106C. The conductor 106B is not depicted in FIG. 3 as having a load thereon. When the predefined load 126 is activated, the metering device 44 will substantially contemporaneously detect the various signals that are received from the connected current transformers 8 and will employ an algorithm to identify the current transformer 8 that is situated about the conductor to which the predefined load 126 is connected. That is, upon the triggering of the predefined load 126 in FIG. 3 and the detection of whatever signals are received from the current transformers 8 attached to the channels 114A, 114B, 114C, an algorithm that is executed on a processor apparatus 134 of the metering device analyzes the signals. The algorithm detects from the signals the presence of the predefined load 126 and responsively provides a visual indication on a display 130 of the metering device 44 that is indicative of the channel 114A, 114B, 114C to which is connected the current transformer 8 that is situated about the conductor to which the predefined load 126 is connected. The processor apparatus 134 includes a processor 138 and a memory 142, with the algorithm being stored in the memory 142 and being executed on the processor 138. The algorithm is sufficiently sophisticated that it can identify the existence of the predefined load 126 even in the presence of other loads, such as the load Y 122 on the same conductor 106C.

Once the metering device 44 has identified the current transformer 8 that is situated about the conductor to which is connected the predefined load 126, i.e., the conductor 106C in FIG. 3, the predefined load 126 is disconnected from that conductor and is connected with other conductors to identify the current transformers 108 that are situated about such other conductors. For instance, the predefined load 126 might be connected to the conductor 106B will identify the current transformer 8 of the current transformer apparatus 104B. Similarly, a connection of the predefined load 126 to the conductor 106A will identify the current transformer apparatus 104A, and, more particularly, the current transformer 8 of the current transformer apparatus 104A, as being situated about the conductor 106A. It is reiterated that the algorithm will be able to distinguish the predefined load 126 from the load X 118 on the conductor 106A to enable identification of the current transformer 8 of the current transformer apparatus 104A.

It is understood that the calibration values stored in the storage 12 of each of the current transformer apparatuses 104A, 104B, 104C are employed in calibrating the current transformers 8 of the current transformer apparatuses 104A, 104B, 104C when connected with the metering device 44. It is also understood, however, that such calibration values are not necessarily employed in identifying that a particular current transformer 8 is situated about a particular conductor 106A, 106B, 106C. As such, the identification of such a current transformer 8 can be performed on any type of current transformer 8, i.e., even when the current transformer 8 does not additionally include calibration values stored on an associated storage 12.

Advantageously, therefore, a current transformer 8 can be configured to allow for automatic calibration by subjecting it to one or more calibration loads and employing a calibration meter and memory programmer 24 to detect a signal from the current transformer 8, to determine a number of calibration values for the current transformer 8 from the signal, and to store the calibration values in a storage 12 disposed on the current transformer 8 to form an improved current transformer apparatus 4. Upon connecting the current transformer apparatus 4 with a metering device 44 and retrieving the calibration values stored in the storage 12, the metering device 44 can apply the calibration values to the signal received from the current transformer 8 to form a calibrated output from the current transformer 8 and to provide a calibrated output on the metering device 44. Further advantageously, a predefined load 126 can be connected with various conductors in order to identify which current transformer 8 is situated about which conductor.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of invention which is to be given the full breadth of the claims appended and any and all equivalents thereof.

What is claimed is:

1. A method of enabling calibration of a current sensor, the method comprising:
applying a known load to a conductor that is disposed in proximity to the current sensor;
detecting from the current sensor a signal responsive to the known load;
deriving from the signal and the known load a number of calibration values for the current sensor; and
storing on the current sensor at least a portion of the number of calibration values.

2. The method of claim 1, further comprising storing the at least portion of the number of calibration values in an electronic storage situated on the current sensor.

3. The method of claim 2, further comprising storing as the at least portion of the number of calibration values at least one of:
a gain value;
a phase correction value; and
a nonlinearity factor usable in a particular current range.

4. The method of claim 2, further comprising storing in the electronic storage at least a first piece of identification data related to an identification of the current sensor.

5. The method of claim 4, further comprising storing as the at least first piece of identification data a data element indicative of an ampere capacity of the current sensor.

6. The method of claim 1, further comprising performing the applying, the detecting, the deriving, and the storing for each of a plurality of other current sensors similar to the current sensor.

7. A current sensor apparatus comprising:
a current sensor structured to be connected with a metering device;
a non-volatile storage disposed on the current sensor and having stored therein a number of calibration values for the current sensor; and
a communications system connected with the storage and structured to communicate at least a portion of the number of calibration values to the metering device.

8. The current sensor apparatus of claim 7 wherein the number of calibration values comprise at least one of:
a gain value;
a phase correction value; and
a nonlinearity factor usable in a particular current range.

9. The current sensor apparatus of claim 7 wherein the storage further has stored therein at least a first piece of identification data related to an identification of the current sensor.

10. The current sensor apparatus of claim 9 wherein the at least first piece of identification data comprises a data element indicative of an ampere capacity of the current sensor.

11. The current sensor apparatus of claim 7 wherein the current sensor is a current transformer.

12. A method of calibrating a current sensor, the method comprising:
connecting the current sensor with a metering device;
retrieving a number of calibration values for the current sensor; and
applying at least a portion of the number of calibration values to a signal received from the current sensor to generate a calibrated output from the metering device.

13. The method of claim 12 wherein a storage having stored therein the number of calibration values for the current sensor is disposed on the current sensor, and wherein the retrieving of the number of calibration values comprises retrieving at least a portion of the number of calibration values from the storage.

14. The method of claim 13 wherein the storage comprises a non-volatile electronic storage and a communications system connected with the electronic storage, and wherein the retrieving comprises receiving the number of calibration values via the communications system.

15. The method of claim 14, further comprising connecting the metering device with the communications system.
